(19) United States
(12) Patent Application Publication
(10) Pub. No.: US 2020/0199710 A1
(43) Pub. Date: Jun. 25, 2020

(54) METHOD FOR SYNTHESIS OF TRANSITION METAL DICHALCOGENIDE ALLOYS USING LIGHT SOURCES AND TRANSITION METAL DICHALCOGENIDE ALLOYS SYNTHESIZED BY THE SAME

(71) Applicant: Korea Advanced Institute of Science and Technology, Daejeon (KR)

(72) Inventors: Sung-Yool CHOI, Daejeon (KR); Gi Woong SHIM, Daejeon (KR)

(73) Assignee: Korea Advanced Institute of Science and Technology, Daejeon (KR)

(21) Appl. No.: 16/716,866

(22) Filed: Dec. 17, 2019

(30) Foreign Application Priority Data
Dec. 20, 2018 (KR) 10-2018-0165868

(51) Int. Cl. C22C 1/02

(52) U.S. Cl. CPC C22C 1/02; H01L 29/24

(57) ABSTRACT

Provided is a method for preparing a transition metal dichalcogenide alloy, which includes: a step of stacking two or more transition metal dichalcogenide compound thin films having different bandgaps on a substrate; a step of irradiating light to the two or more transition metal dichalcogenide compound thin films having different bandgaps; and a step of preparing a transition metal alloy by evaporating a dichalcogenide compound of the transition metal dichalcogenide compound thin film by the light.

### CROSS-REFERENCE TO RELATED APPLICATIONS

This application claims the benefit under 35 USC § 119(a) of Korean Patent Application No. 10-2018-0165868 filed on Dec. 20, 2018, in the Korean Intellectual Property Office, the entire disclosure of which is incorporated herein by reference for all purposes.

### TECHNICAL FIELD

The present disclosure relates to a method for preparing a transition metal dichalcogenide alloy using a light source, more particularly to a method for preparing a transition metal dichalcogenide alloy using a light source, which satisfies high mobility and high on/off ratio at the same time.

### BACKGROUND ART

Although there have been many efforts to discover high-mobility materials for driving a TFT of a display, the only materials commercialized at present are LTPS and oxide semiconductors (a-IGZO) with mobility of tens of cm²/Vs. Such a low mobility is the major obstacle to display performance. Although the industry aims at improving mobility by changing the process conditions of laser annealing of LTPS or the composition of a-IGZO, there has been no noticeable innovation due to the intrinsic limitation of the materials (for monocrystalline Si, the maximum mobility is ˜1,000 cm²/V·s).

Therefore, efforts are being made to discover new materials. But, there is a limitation that the mobility is inversely proportional to the bandgap. The mobility is increased as the bandgap is smaller. However, the on/off ratio is decreased due to increased leakage current because the thermal excitation of charge carrier becomes easier. This leads to unwanted increase in power consumption and slow switching.

Accordingly, a material having high mobility as well as an adequate bandgap is required. FIG. 1 shows an experimentally determined mobility-bandgap diagram.

Referring to FIG. 1, because materials with a bandgap in the infrared region have a steep mobility-bandgap relationship and materials with a bandgap in the visible region have a gentle mobility-bandgap relationship, it is difficult to find a material having a high on/off ratio as well as a high mobility in the nature.

Diamond is an exception because it has a bandgap 5.47 eV and a hold mobility of ˜2,000 cm²/V·s [Mater. Today 11, 22 (2008)]. However, most materials follow the empirical law of E_{g}˜μ⁻¹.

Accordingly, a new alloy satisfying high on/off ratio and mobility at the same time and a method for preparing the same are necessary.

### DISCLOSURE

### Technical Problem

The present disclosure is directed to providing a new alloy satisfying high on/off ratio and mobility at the same time and a method for preparing the same.

### Technical Solution

The present disclosure provides a method for preparing a transition metal dichalcogenide alloy, which includes: a step of stacking two or more transition metal dichalcogenide compound thin films having different bandgaps on a substrate; a step of irradiating light to the two or more transition metal dichalcogenide compound thin films having different bandgaps; and a step of preparing a transition metal alloy by evaporating a dichalcogenide compound of the transition metal dichalcogenide compound thin film by the light.

In an exemplary embodiment of the present disclosure, the light heats the thin films to a temperature higher than the evaporation temperature of the dichalcogenide compound, and the light is irradiated in a pulsed manner.

In an exemplary embodiment of the present disclosure, the alloy includes a metallic bond between transition metals of the two or more transition metal dichalcogenide compound thin films having different bandgaps.

The present disclosure also provides a transition metal dichalcogenide alloy prepared by the method for preparing a transition metal dichalcogenide alloy described above.

### Advantageous Effects

According to the present disclosure, a two-dimensional alloy material, which is metastable, or requires a very large energy barrier for synthesis, may be synthesized using the strong light (laser, flash lamp)-material interaction whereby heat penetrates and vanishes on a very fast time scale. Because the surface properties of the two-dimensional material occupy a larger fraction of the overall properties as compared to the existing three-dimensional materials, the material has an alloy structure due to its energy and very small thickness. As a result, a new alloy satisfying on/off ratio and mobility at the same time can be prepared.

### BRIEF DESCRIPTION OF DRAWINGS

FIG. 1 shows an experimentally determined mobility-bandgap diagram.

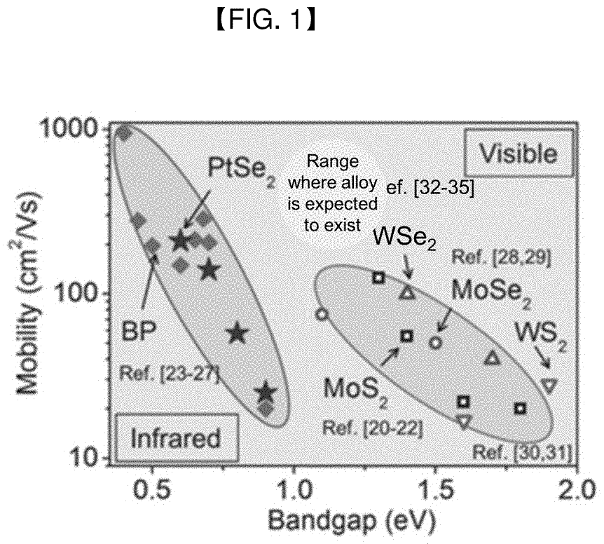

FIG. 2 schematically shows an alloy according to an exemplary embodiment of the present disclosure and a method for preparing the same.

FIG. 3 shows a block diagram of a method for preparing an alloy according to an exemplary embodiment of the present disclosure.

### BEST MODE

Hereinafter, specific exemplary embodiments of the present disclosure are described in detail referring to the attached drawings. In the attached drawings, it should be noted that like numerals refer to like elements. Also, a detailed description of a generally known function and structure will be avoided lest it should obscure the subject matter of the present disclosure. For the same reason, some elements in the attached drawings are exaggerated, omitted or illustrated schematically.

Also, throughout the present disclosure, the term “include” does not preclude the existence of other elements unless clearly stated otherwise. In addition, throughout the present disclosure, “on” does means the presence above or below an object and does not necessarily mean the presence on the upper side based on the gravitational direction.

The present disclosure is directed to providing a material alloy having an appropriate bandgap (˜1.0 eV) and high mobility, which is an alloy of a two-dimensional (2D) material having a low bandgap and a 2D material having a high bandgap, and a method for preparing the same.

According to the prior art, the following conditions should be satisfied to prepare a 2D alloy material.

1) The lattice mismatch should be 1% or smaller.

2) The number of electrons participating in bonding and the electronic configuration of the transition metal should be similar.

However, even if 1) and 2) are satisfied, there is no significant change in physical properties because similar elements are mixed to form an alloy. For example, an alloy based on a transition metal such as Mo and W and a chalcogen such as S and Se is advantageous in that the bandgap can be controlled in a range from 1.7 (MoS₂) to 2.0 (WSe₂) eV based on composition, but electrical properties, etc. are not improved greatly. That is to say, a 2D material alloy that can be synthesized in thermal equilibrium state while satisfying the natural laws has properties simply expectable from the mixing ratio.

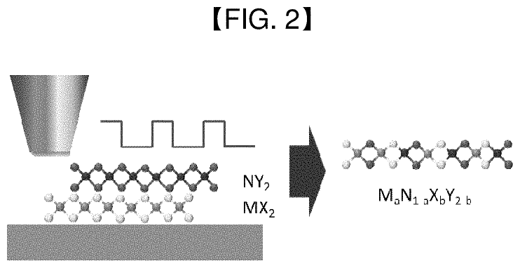

FIG. 2 schematically shows an alloy according to an exemplary embodiment of the present disclosure and a method for preparing the same.

Referring to FIG. 2, light is irradiated to an alloy with very short time intervals. That is to say, a 2D alloy material, which is metastable, or requires a very large energy barrier for synthesis, may be synthesized using the strong light (laser, flash lamp)-material interaction whereby heat penetrates and vanishes on a very fast time scale.

Because the surface properties of the two-dimensional material occupy a larger fraction of the overall properties as compared to the existing three-dimensional materials, the material has an alloy structure due to its energy and very small thickness

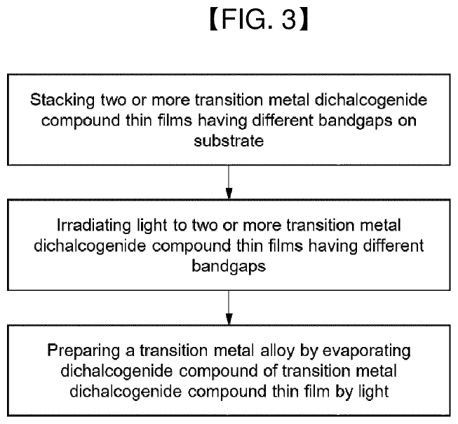

FIG. 3 shows a block diagram of a method for preparing an alloy according to an exemplary embodiment of the present disclosure.

Referring to FIG. 3, in a method for preparing an alloy according to an exemplary embodiment of the present disclosure, two-dimensional materials having different bandgaps are stacked sequentially on a substrate. In the present disclosure, the two-dimensional material is a transition metal dichalcogenide compound.

Then, light is irradiated to the two-dimensional materials having different bandgaps. For example, light is irradiated to transition metal dichalcogenide compound thin films using a laser or a flash lamp with very short time intervals. That is to say, the thin films are heated to a temperature higher than the evaporation temperature of the dichalcogenide compound by the irradiated light.

In an exemplary embodiment of the present disclosure, a low-bandgap material such as PtSe₂ and an intermediate-bandgap material such as MoS₂ are epitaxially grown by CVD. Then, light is irradiated thereto. The dichalcogenide is evaporated faster than the transition metal because it has a lower melting/boiling point. That is to say, it is preferable that the light irradiated in the present disclosure has an energy lower than that required to melt the transition metal but higher than that required to melt the dichalcogenide compound. If the energy is higher than required to melt the transition metal, the transition metal will be melted rather than being diffused on the surface.

As the transition metal is diffused on the surface below its melting point, an alloy material such as PtₓMo₁₋ₓS_{y}Se_{2-y} may be synthesized through formation of bonding between the transition metals.

A theoretical simulation technique may be used to develop this new material. For prediction of mobility at room temperature, physical properties (phonon distribution, piezoelectric tensor, etc.) should be considered in addition to electronic structure. Molecular dynamics simulation may be utilized for energy calculation for several phases due to the mixing of different elements and prediction of spontaneous phase separation.

1. A method for preparing a transition metal dichalcogenide alloy, comprising:
a step of stacking two or more transition metal dichalcogenide compound thin films having different bandgaps on a substrate;
a step of irradiating light to the two or more transition metal dichalcogenide compound thin films having different bandgaps; and
a step of preparing a transition metal alloy by evaporating a dichalcogenide compound of the transition metal dichalcogenide compound thin film by the light.

2. The method for preparing a transition metal dichalcogenide alloy according to claim 1, wherein the light heats the thin films to a temperature higher than the evaporation temperature of the dichalcogenide compound.

3. The method for preparing a transition metal dichalcogenide alloy according to claim 1, wherein the light is irradiated in a pulsed manner.

4. The method for preparing a transition metal dichalcogenide alloy according to claim 1, wherein the alloy comprises a metallic bond between transition metals of the two or more transition metal dichalcogenide compound thin films having different bandgaps.

5. A transition metal dichalcogenide alloy prepared by the method for preparing a transition metal dichalcogenide alloy according to claim 1.
